(19) United States
(12) Patent Application Publication
(10) Pub. No.: US 2021/0091733 A1
(43) Pub. Date: Mar. 25, 2021

(54) FEEDBACK-BASED POWER SUPPLY FOR RADIO-FREQUENCY POWER AMPLIFIER

(71) Applicant: SHAANXI REACTOR MICROELECTRONICS CO., LTD, Xi'an (CN)

(72) Inventor: Qin XIA, XI'AN (CN)

(73) Assignee: SHAANXI REACTOR MICROELECTRONICS CO., LTD

(21) Appl. No.: 17/060,250

(22) Filed: Oct. 1, 2020

Related U.S. Application Data
(63) Continuation of application No. PCT/CN2020/092350, filed on May 26, 2020.

(30) Foreign Application Priority Data
May 27, 2019 (CN) 201910449103.9

(51) Int. Cl. H03F 3/24; H03F 1/02; H03F 3/19

(52) U.S. Cl. CPC H03F 3/245; H03F 1/0222; H03F 2200/102; H03F 2200/451; H03F 3/19

(57) ABSTRACT

A feedback-based power supply for a radio-frequency power amplifier includes: a linear amplification unit, a first controlling unit, a first driving unit, a first feeding-back unit and a superimposing unit, and the first controlling unit obtains a feedback signal of a change rate of an electrical signal of a supply voltage end of the radio-frequency power amplifier through the first feeding-back unit and outputs a first control signal to enable the power supply to work in any one of the following modes: a constant on time control mode having a constant on time and a constant off time control mode having a constant off time; the first driving unit is configured to connect an output end of the first controlling unit and provide a first electrical signal based on the first control signal.

### CROSS REFERENCE TO RELATED APPLICATIONS

This application is a continuation of International Patent Application No. PCT/CN2020/092350 with a filing date of May 26, 2020, designating the United States, now pending, and further claims priority to Chinese Patent Application No. 201910449103.9 filed on May 27, 2019, the entire content of which is incorporated herein by reference.

### TECHNICAL FIELD

The present invention relates to the field of mobile communication, and in particular to a feedback-based power supply for a radio-frequency power amplifier.

### BACKGROUND

In the field of mobile communication, a hybrid power supply in which a linear amplification unit is combined with a switching power supply may be used to improve the efficiency of a radio-frequency power amplifier. Such hybrid power supplies usually adopt hysteresis control.

Although technology is developing continuously, how to further improve the power supply efficiency of the radio-frequency power amplifier always remains a technical problem to be considered in this field.

### SUMMARY

To solve the above technical problem, the present invention provides a feedback-based power supply for a radio-frequency power amplifier, including:

a linear amplification unit, a first controlling unit, a first driving unit, a first feeding-back unit and a superimposing unit.

The linear amplification unit is configured to linearly amplify a first envelope signal and output the linearly-amplified envelope signal.

The first controlling unit includes a first input end configured to receive the linearly-amplified envelope signal.

The first controlling unit further includes a second input end configured to obtain a feedback signal of a change rate of an electrical signal of a supply voltage end of the radio-frequency power amplifier through the first feeding-back unit.

The first controlling unit further includes an output end, where the first controlling unit outputs a first control signal based on inputs of the first input end and the second input end so that the power supply works in any one of the following modes: a constant on time control mode having a constant on time and a constant off time control mode having a constant off time.

The first driving unit is configured to connect the output end of the first controlling unit and provide a first electrical signal based on the first control signal.

The superimposing unit is configured to superimpose the linearly-amplified envelope signal and the first electrical signal so as to supply power to the supply voltage end of the radio-frequency power amplifier.

Preferably, the first envelope signal is an envelope signal input into the radio-frequency power amplifier.

Preferably, the change rate of the electrical signal of the supply voltage end includes any one or any combination of: a change rate of a voltage, a change rate of an electric current and a change rate of an envelope amplitude.

Preferably, the first driving unit includes a first switching amplifier or includes an upper power transistor and a lower power transistor.

Preferably, the power supply further includes a first mode selecting unit configured to perform selection between the constant on time control mode and the constant off time control mode.

Preferably, the first controlling unit includes a timing unit configured to determine the constant on time or the constant off time.

Preferably, when a value of the first electrical signal is less than a first threshold, the first controlling unit is further configured to force the power supply to continuously provide the first electrical signal in the constant on time control mode or the constant off time control mode so that the value of the first electrical signal is greater than or equal to the first threshold.

Preferably, the first driving unit includes at least a first switching amplifier and a second switching amplifier connected in parallel, and the first controlling unit is further configured to enable the first switching amplifier and the second switching amplifier to work in the constant on time control mode or the constant off time control mode according to a time sequence.

Preferably, the constant on time or the constant off time of at least one switching amplifier is different from that of other switching amplifiers.

Preferably, when the value of the electrical signal in a branch to which any switching amplifier connected in parallel belongs is less than a threshold of the branch, the first controlling unit is further configured to force the power supply to continuously provide the electrical signal in the branch to which any switching amplifier belongs in the constant on time control mode or the constant off time control mode so that the value of the electrical signal in the branch is greater than or equal to the threshold of the branch; or

when the values of the electrical signals in the branches to which all switching amplifiers connected in parallel belong are added as the value of the first electrical signal, if the value of the first electric signal is less than the first threshold, the first controlling unit is further configured to force the power supply to continuously provide the first electrical signal in the constant on time control mode or the constant off time control mode so that the value of the first electrical signal is greater than or equal to the first threshold.

Through the above technical solution, the present invention realizes a new power supply for a radio-frequency power amplifier, which is capable of further controlling the first driving unit to work in the constant on time mode or the constant off time mode based on the change rate of the electrical signal of the supply voltage end outside the linear amplification unit. Therefore, it is helpful to improving a utilization rate of the first driving unit and an efficiency of the entire power supply.

### BRIEF DESCRIPTION OF THE DRAWINGS

FIG. 1 is a structural schematic diagram of a power supply according to an embodiment of the present invention.

FIG. 2A is a schematic diagram illustrating a first driving unit of a power supply according to an embodiment of the present invention.

FIG. 2B is a schematic diagram illustrating a first driving unit of a power supply according to another embodiment of the present invention.

FIG. 2C is a structural schematic diagram of a power supply according to another embodiment of the present invention.

FIG. 2D is a schematic diagram illustrating a time sequence according to an embodiment of the present invention.

FIG. 2E is a structural schematic diagram of a power supply according to still another embodiment of the present invention.

FIG. 3A (1) is a simulation diagram of a traditional hysteresis control power supply in a case of a first envelope signal being a signal of 100 MHz.

FIG. 3B (1) is a switching waveform of a driving unit corresponding to a switching power supply of the traditional hysteresis control power supply.

FIG. 3A (2) is a simulation diagram of a power supply in a case of the same first envelope signal being the signal of 100 MHz according to an embodiment of the present invention.

FIG. 3B (2) is a switching waveform of a driving unit corresponding to a switching power supply of the power supply according to the embodiment of the present invention.

FIG. 3C (1) illustrates a comparison of switching frequency distributions of the traditional hysteresis control power supply and the power supply according to the embodiment of the present invention described above.

FIG. 3C (2) illustrates a comparison of switch-on time distributions of the traditional hysteresis control power supply and the power supply according to the embodiment of the present invention described above.

FIG. 3D (1) illustrates a power simulation of each unit of the above traditional hysteresis control power supply in a working process.

FIG. 3D (2) illustrates a power simulation of each unit of the above power supply according to the embodiment of the present invention in a working process.

FIG. 3E (1) illustrates a comparison situation of change curves of output powers, along with a frequency, of the traditional hysteresis control power supply and the power supply according to the embodiment of the present invention within a low frequency range of 0 MHz to 100 MHz.

FIG. 3E (2) illustrates a comparison of change curves of the output powers, along with a frequency, of the traditional hysteresis control power supply and the power supply according to the embodiment of the present invention within a lower frequency range of 0 MHz to 25 MHz.

### DETAILED DESCRIPTION OF THE EMBODIMENTS

In the following descriptions, several details are set forth to provide a more complete explanation to the embodiments of the present invention. However, it is apparent that those skilled in the art may implement the embodiments of the present invention without these specific details. In other embodiments, well-known structures and devices are illustrated in the form of block diagram rather than in details to avoid obscuring the embodiments of the present invention. In addition, features of different embodiments described below may be combined with each other, unless otherwise specifically stated.

Terms such as “first” and “second” used herein are intended to distinguish different objects rather than describe a specific order. In addition, terms “including” and “having” and any variation thereof are intended to encompass non-exclusive inclusion. For example, a process, method, system, product or device including a series of steps or units is not limited to listed steps or units, but optionally further includes unlisted steps or units, or optionally further includes other steps or units inherent to such a process, method, system, product or device.

The “embodiment” mentioned herein means that specific features, structures, or characteristics described in combination with the embodiments may be included in at least one embodiment of the present invention. The described embodiments are part of embodiments of the present invention rather than all embodiments. The phrases appearing at different positions in the specification neither necessarily all refer to the same embodiment nor refer to independent or optional embodiments repulsive to other embodiments. Those skilled in the art may understand that the embodiments described herein may be combined with other embodiments.

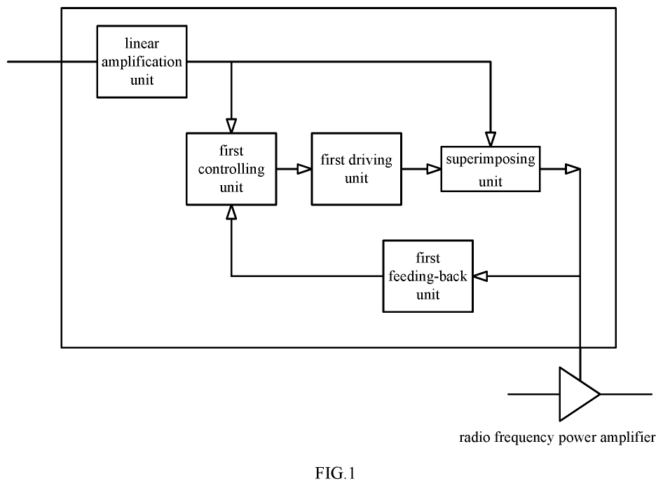

As shown in FIG. 1, in an embodiment, the present invention provides a feedback-based power supply for a radio-frequency power amplifier, including:

a linear amplification unit, a first controlling unit, a first driving unit, a first feeding-back unit and a superimposing unit.

The linear amplification unit is configured to linearly amplify a first envelope signal and output the linearly-amplified envelope signal.

The first controlling unit includes a first input end configured to receive the linearly-amplified envelope signal.

The first controlling unit further includes a second input end configured to obtain a feedback signal of a change rate of an electrical signal of a supply voltage end of the radio-frequency power amplifier through the first feeding-back unit.

The first controlling unit further includes an output end, where the first controlling unit outputs a first control signal based on inputs of the first input end and the second input end so that the power supply works in any one of the following modes: a constant on time control mode having a constant on time and a constant off time control mode having a constant off time.

The first driving unit is configured to connect the output end of the first controlling unit and provide a first electrical signal based on the first control signal.

The superimposing unit is configured to superimpose the linearly-amplified envelope signal and the first electrical signal so as to supply power to the supply voltage end of the radio-frequency power amplifier.

In this embodiment, a supply voltage of the radio-frequency power amplifier is provided by superimposing the linearly-amplified envelope signal and the first electrical signal, which is totally different from the fact that a supply voltage of a radio-frequency power amplifier is provided to the radio-frequency power amplifier through a single voltage or after parallel-connecting two electric currents in the prior art. The linearly-amplified envelope signal and the first electric signal are both related to the first envelope signal. Therefore, the above embodiment realizes a new power supply for envelop tracking. It can be understood that in the presence of the first envelope signal, the above feedback-based power supply for a radio-frequency power amplifier is generated based on the linear amplification unit, the first controlling unit, the first feeding-back unit, the first driving unit and the superimposing unit.

It can be understood that the first controlling unit may be any constant on/off time (COT) controlling unit capable of realizing COT control. The COT includes Constant On Time and Constant Off Time. It is to be noted that the present invention does not focus on innovative realization of the COT controlling unit. Therefore, different COT controlling units in the prior art all may be employed, including a timer or a time counter possibly involved in the COT control, or another circuit or functional unit cooperating with the timer or the time counter, with its main purpose of calculating and determining a corresponding constant on time or constant off time.

In other words, the above embodiment is also obviously different from the existing power supply including a filtering unit and a hysteresis control implemented after filtering. The above embodiment adopts the COT control rather than the filtering unit and the hysteresis control, so that a frequency of the first driving unit is not subjected to limitations such as a circuit parameter L, an equivalent load, hysteresis, a loop delay and an input signal. It is very easy to perform rapid response and adjustment for the on time or off time of the first driving unit through the first controlling unit, thereby improving the efficiency. That is, compared with the prior art in which the filtering and the after-filtering hysteresis control are adopted, the above embodiment not only has a simple solution and a high efficiency, but also can eliminate the jitter of the control signal and reduce a noise. Further, due to a high response speed, the COT control is very applicable to an application scenario such as envelope tracking requiring a large input signal bandwidth and ease of expansion.

It is more particularly noted that controlling the first driving unit to enable the power supply to work in the constant on time mode or the constant off time mode indicates that the first driving unit enables the power supply to have the characteristic of a switching power supply. Further, since the power supply includes the linear amplification unit, the power supply is a hybrid envelope tracking power supply combining two characteristics of linear amplification and the switching power supply. However, with rapid development of wireless communication technology, a 5G commercialization era will come up, and 6G technology is already in the research stage. In the face of sharp increase of different service data such as mobile Internet, a peak-to-average power ratio (PAPR) of a radio-frequency input signal becomes larger and larger, resulting in a very low efficiency of the linear amplification unit of the constant-voltage power supply in a case of a large PAPR.

Obviously, the above embodiment is helpful to solving the problem of the reduced efficiency of the entire power supply resulting from the very low efficiency of the linear amplification unit at the large PAPR. In the above embodiment, further controlling the first driving unit to enable the power supply to work in the constant on time mode or the constant off time mode based on the change rate of the electrical signal of the supply voltage end outside the linear amplification unit helps increase a proportion of the switching power supply in the entire power supply and reduce a proportion of the linear amplification unit according to the change rate of the electrical signal of the supply voltage end. Thus, the advantage of high efficiency of the switching power supply is brought to full play. Therefore, the above embodiment is helpful to further improving the efficiency of the entire power supply.

In addition, in the above embodiment, controlling the first driving unit to enable the power supply to work in the constant on time mode or the constant off time mode based on the change rate of the electrical signal of the supply voltage end outside the linear amplification unit further realizes the following: the first driving unit in the power supply enables the power supply to exhibit the characteristic of the switching power supply externally, and the switching-on and off of such switching power supply are not subjected to the envelope signal bandwidth but the change rate of the electrical signal of the supply voltage end. This also indicates that the power supply disclosed in the above embodiment has a stronger anti-interference capability, and thus is helpful to increasing the proportion of the switching power supply in the entire power supply working process. Therefore, the efficiency of the entire power supply is improved by utilizing the high-efficiency characteristic of the switching power supply.

Matching of a time constant or time delay of each circuit itself belongs to common knowledge of the circuit field. The present invention also does not focus on how to design and adjust the time constant, and thus will not make the descriptions redundantly.

It can be understood that the signal in the above embodiment may be an electric current signal or a voltage signal. Different electrical signals described below are similar to the above signals, which will not be described in detail below. Similarly, the power supply of the above embodiment may be an analog power supply or a digital power supply as long as it can be realized in a manner of an analog circuit or a digital circuit.

In addition, when the radio-frequency power amplifier is determined to be at light load or no load, the constant on time mode is preferable in the above embodiment. The reason is that compared with increase of switching loss and reduction of the efficiency of the power supply resulting from the constant off-time mode at the light load, the constant on time mode is more conducive to reducing the switching loss and improving the efficiency of the power supply at the light load or no load.

In addition, it is to be noted that for a functional implementation of the superimposing unit, if the power supply of the above embodiment is an analog power supply, (1) when the signal output by the first driving unit is an electric current signal, circuits corresponding to the signal and the linearly-amplified envelope signal respectively may realize electric current superimposition by parallel connection; (2) when the signal output by the first driving unit is a voltage signal, circuits corresponding to the signal and the linearly-amplified envelope signal respectively may realize voltage superimposition by series connection. In addition, if the power supply of the above embodiment is a digital power supply, as long as digital circuits can superimpose the digital signals of the signal output by the first driving unit and the linearly-amplified envelope signal, these digital circuits all may be used to implement the present invention. If the analog power supply or the digital power supply described above is involved in each of the following embodiments, its descriptions are similar to those in this paragraph.

In another embodiment, the first envelope signal is an envelope signal input into the radio-frequency power amplifier.

In this embodiment, when the first envelope signal is the envelope signal input into the radio-frequency power amplifier, as a radio-frequency (RF) input signal is taken as a reference signal of envelope tracking in most technical solutions in the prior art, envelope tracking is also realized from a signal source, i.e. the envelope signal input into the radio-frequency power amplifier in this embodiment. However, this does not mean that the present invention excludes other first envelope signals. It is apparent that the relevant embodiments are not limited to the source of the envelope signals in terms of achieving technical effects of different embodiments described above according to principles disclosed by the present invention.

In another embodiment, the change rate of the electrical signal of the supply voltage end includes any one or combination of: a change rate of a voltage, a change rate of an electric current, a change rate of an envelope amplitude.

In this embodiment, the change rate of the voltage of the supply voltage end is a derivative of the voltage of this end with respect to time; the change rate of the electric current is a derivative of the electric current with respect to time; the change rate of the envelope amplitude is a derivative of the envelope amplitude with respect to time. Methods of detecting and processing the above change rates of the voltage, the electric current and the envelope amplitude in the prior art may all be used, which are not limited herein. Further, the corresponding first feeding-back unit may be specifically implemented as a slew rate processing unit, an electric current slope rate or change rate processing unit and an envelope slew rate processing unit.

In the traditional hysteresis control power supply, a voltage value of an output end of the power supply is usually compared with a set reference voltage by a comparator to determine an on-time point of a corresponding driving unit, which is sensitive to an output noise and easily results in wrong switching-on. However, the sensitivity to the noise and the bandwidth of the envelope signal is reduced by feeding back the signal change rate of the supply voltage end (also referred to as a power input end) of the power amplifier in the present invention. Therefore, when the power supply works with the switching power supply, the on-time point of the power supply is fixed at an optimal position more accurately, and on and off frequencies are limited to a certain range, thereby realizing a jitter frequency required for Electro-Magnetic Interference (EMI) immunity without affecting linearity of a power supply system and also facilitating improving the efficiency of the entire power supply significantly.

It can be understood that the change rate of the voltage, the change rate of the electric current and the change rate of the envelope amplitude may be obtained through different detecting or sensing elements. Typically, the above change rates may be sensed through an inductor or capacitor, or the change rate of the voltage, the change rate of the electric current and the change rate of the envelope amplitude may be obtained by performing further calculation with sensing elements collecting the voltage or the electric current or the envelope amplitude at high speed and a particular controller or processor. Preferably, a more sensitive inductor and/or capacitor may be adopted to obtain, at a low cost, any one or combination of: the change rate of the voltage, the change rate of the electric current and the change rate of the envelope amplitude.

In another embodiment, when the change rate of the electrical signal of the supply voltage end is less than a particular change rate threshold, the first controlling unit is further configured to control the first driving unit to force the power supply to work in the constant on time mode or the constant off time mode.

It can be understood that this is to increase the proportion of the switching power supply in the entire power supply as possible. No matter whether the switching power supply works in the constant on time mode or the constant off time mode in the entire power supply, the change rate threshold should be as low as possible. Meanwhile, it can be understood that if there is no the change rate threshold, the power supply can still be enabled to work in the constant on time mode or the constant off time mode only according to the change rate of the electrical signal of the supply voltage end in the above embodiment. For example, the first driving unit is controlled to work or not and to work at what frequency according to a specific value of the change rate of the electrical signal of the supply voltage end, thereby enabling the power supply to work in the constant on time mode or the constant off time mode.

More preferably, the change rate threshold may be preset, and may even be changeable. Although the change rate threshold should be as low as possible theoretically, the change rate threshold may be preset according to a differential signal of a maximum working bandwidth (note: the bandwidth is known information and may be obtained in various manners) of the envelope signal to be processed, and may be changed and updated according to different envelope signals in different working scenarios. As a result, the loss caused by frequent switching is reduced and the entire power supply efficiency is optimized.

The change rate of the voltage is taken as an example. Generally, for the envelope signal in the current radio-frequency communication technology, the change rate threshold may be selected in the range of 900 V/μs-1800 V/μs.

Specifically, in each on and off period of the first driving unit, when the voltage change rate SR s4 of the supply voltage end of the radio-frequency power amplifier is greater than or equal to the change rate threshold, an on-time timing module in the first controlling unit is triggered. When the COT control is performed in the manner of constant on time, the constant on time Ton starts timing, and the first driving unit starts turning on and turns off when timing is ended. It can be understood that if the COT control is performed in the manner of constant off time, the constant off time Toff may be further set with a minimum off time to satisfy a time length required for circuit signal collection.

The on-time timing module is configured to determine the constant on time and/or the constant off time, and may be any element, device, apparatus or circuit for implementing a timing or time counting function in the prior art.

In another embodiment, the first driving unit includes a first switching amplifier or includes an upper power transistor and a lower power transistor.

It is obvious that the switching amplifier is configured to be implemented as the driving unit of the switching power supply.

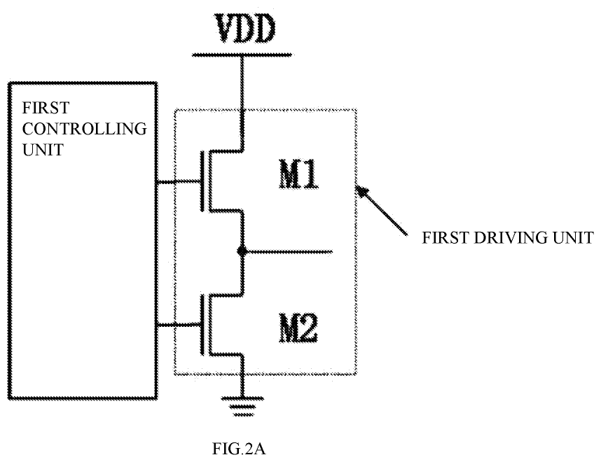

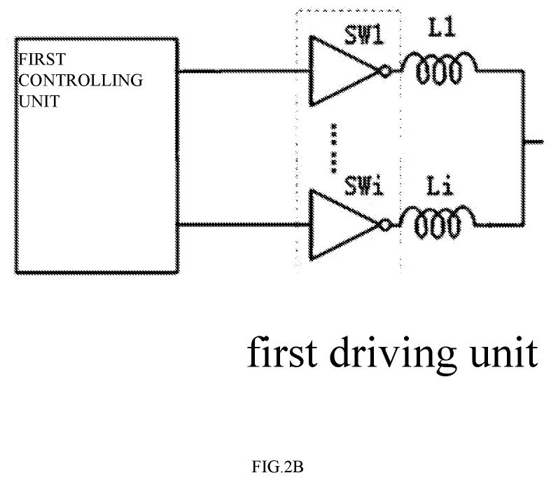

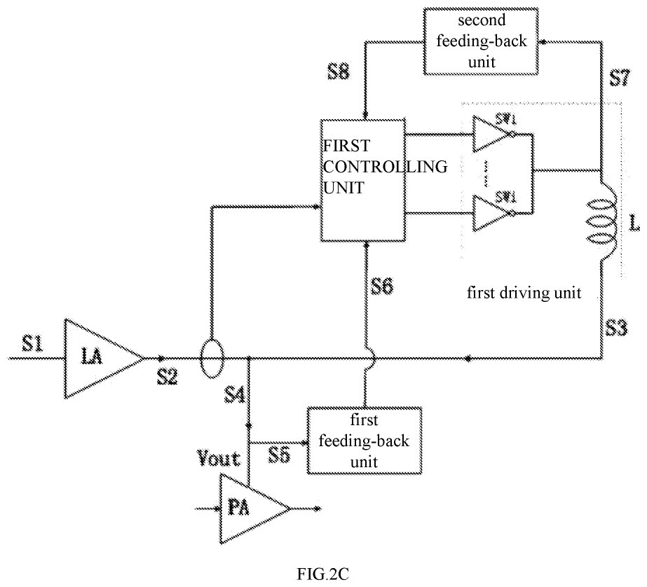

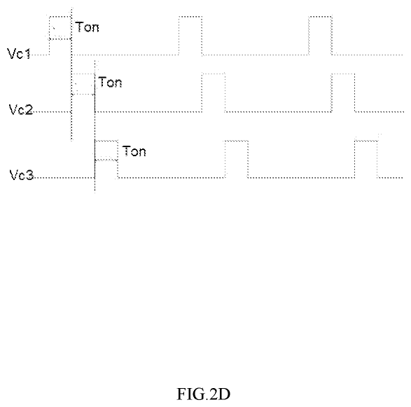

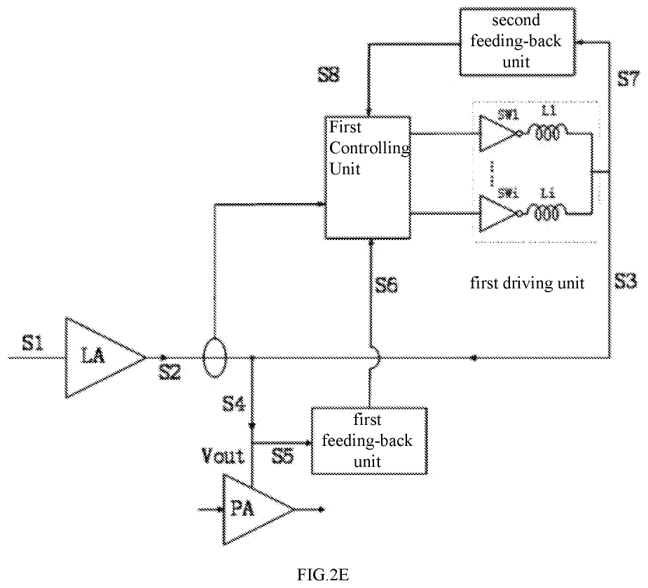

In this embodiment, as shown in FIG. 2A, for example, the first driving unit includes an upper power transistor M1 and a lower power transistor M2.

As shown in FIG. 2A, the first driving unit includes the upper power transistor M1 and the lower power transistor M2, where one end of M1 is connected to a VDD power supply, one end of M2 is grounded, a common end of M1 and M2 is an output end, and gate electrodes of M1 and M2 are connected with an output end of the controlling unit respectively so that on or off is realized based on a gate voltage provided by the first controlling unit.

Further, by referring to the voltage change rate and the change rate threshold described in the previous embodiment, when the voltage change rate of the supply voltage end of the radio-frequency power amplifier is greater than or equal to the change rate threshold in each period, the first controlling unit outputs a control signal to drive the upper power transistor M1 to be on (M2 is in an off state at this time), and starts up the on-time timing module to start timing at the same time; when the timing is ended, the first controlling unit outputs a control signal to drive the upper power transistor M1 to be off and M2 to be on.

In another embodiment, the power supply further includes a first mode selecting unit configured to perform selection between the constant on time control mode and the constant off time control mode.

This embodiment provides an implementation of mode selection, that is, selection is performed by the first mode selecting unit. It can be understood that the selection may be implemented by a hardware circuit or through software calculation. In addition, as described above, when the radio-frequency power amplifier determined to be at light load or no load, the constant on time control mode may also be further preferred regardless of the hardware circuit or the software calculation.

As described above, in another embodiment, the first controlling unit includes a timing unit configured to determine the constant on time or the constant off time.

It is to be noted that all corresponding approaches in the prior art may be adopted to determine the constant on time or the constant off time, which will not be described in detail in the present invention.

In another embodiment, when the value of the first electrical signal is less than the first threshold, the first controlling unit is further configured to force the power supply to continuously provide the first electrical signal in the constant on time control mode or the constant off time control mode so as to achieve the following control purpose that the value of the first electrical signal is greater than or equal to the first threshold.

In this embodiment, the first threshold is used to avoid, as possible, unstable operation of the power supply occurring possibly in some cases. In the absence of the approaches relating to the first threshold, the power supply may still work stably. That is, the embodiment is auxiliary and enhanced type. The reason is that during an engineering, for some radio frequency systems, it is extremely improbable that the sensing elements cannot sense the change rate of the signals of the supply voltage end in time due to smooth change of the envelope signals, which causes the first driving unit to fail to enable the power supply to work in the constant on time control mode or the constant off time control mode, that is, the characteristics of the switching power supply in the power supply are not externally exhibited. Therefore, it can be understood that in the present embodiment, the first controlling unit is enabled to forcibly start the COT control mode of the power supply in this circumstance so as to avoid the case that the COT control mode cannot be started due to smooth change of the signals of the supply voltage end, thereby improving the reliability of the entire power system in an extreme circumstance.

It can be understood that it is better to make the first threshold as low as possible. For example, the first threshold is a value approximate to zero, preferably zero.

It is to be noted that the value of the first electrical signal may be obtained within the first driving unit and then output to the first controlling unit, or may be processed via the second feeding-back unit and then fed back to the first controlling unit (specifically refer to relevant paragraphs of FIG. 2C below). It can be understood that the first controlling unit may be set with a corresponding third input end to receive the value of the first electrical signal at this time.

In another embodiment, the first driving unit includes a first switching amplifier and a first inductor.

It can be understood that the switching amplifier, especially a GaN switching amplifier, is applicable to a scenario with a high frequency. The electric current in the branch may be stored and released by a corresponding first inductor. In addition, if necessary, a capacitor may be further included as an energy storing apparatus.

As shown in FIG. 2B, in another embodiment, the first driving unit includes at least a first switching amplifier and a second switching amplifier connected in parallel, and the first controlling unit is further configured to enable the first switching amplifier and the second switching amplifier to work in the constant on time control mode or the constant off time control mode according to a time sequence.

It can be understood that the above embodiment can realize multi-phase control since a plurality of switching amplifiers are controlled according to the time sequence.

In addition, a reference is made to the previous embodiment. In the embodiment shown in FIG. 2B, the branch to which each switching amplifier belongs may include a corresponding inductor.

As described above, in another embodiment, the first switching amplifier and the second switching amplifier may be selected from any one of: a GaN switching amplifier and a Si-based switching amplifier. Obviously, the embodiment is used for a high-frequency signal since a switching frequency of the GaN switching amplifier may achieve a very high level. Similarly, the Si-based switching amplifier (i.e., a silicon-based switching amplifier) with a very high switching frequency may also be adopted. It can be understood that there will be more options for the relevant switching amplifier if it is not required to process the high-frequency signal. For each embodiment of the present invention, the selection of the switching amplifier depends on a frequency range of the signal to be processed by the switching amplifier.

As shown in FIG. 2C, in another embodiment, for example, i switching amplifier are connected in parallel and then series-connected with one inductor.

In the drawing, LA refers to a linear amplification unit, for example, the linear amplification unit may be at least one of a type-A linear amplifier and a type-AB linear amplifier;

PA refers to a radio-frequency power amplifier;

Vout refers to a voltage output end of the power supply which is connected to the supply voltage end of the radio-frequency power amplifier;

S1 refers to a first envelope signal, S2 refers to a linearly-amplified envelope signal, S3 refers to a first electrical signal, S4 refers to a signal after S2 and S3 are superimposed (where a superimposing unit is not shown), S5 refers to a feedback signal of S4, S6 refers to a signal output from a first feeding-back unit to a first controlling unit, that is, a signal of a second input end of the first controlling unit, S7 refers to a value of the first electrical signal, and S8 refers to a feedback signal that is output from a second feeding-back unit to the first controlling unit and reflects the first electrical signal;

the first controlling unit is connected to i switching amplifiers of the first driving unit; S7 may be led out from any end of an inductor L.

Further, i=3 is taken as an example, which is referred to in FIG. 2D.

As shown in FIG. 2D, the first controlling unit provides a constant on/off time control signal to each switching amplifier according to a time sequence, and each switching amplifier is turned on according to the time sequence and outputs a driving signal. The first controlling unit outputs a control signal Vc1 having a constant on time Ton to the first switching amplifier, outputs a control signal Vc2 having a constant on time Ton to the second switching amplifier, and outputs a control signal Vc3 having a constant on time Ton to a third switching amplifier. The control signal Vc2 is enabled when the control signal Vc1 turns on a falling edge of a pulse. Similarly, the control signal Vc3 is enabled when the control signal Vc2 turns on the falling edge of the pulse. Therefore, the first driving unit realizes the multi-phase control in the control manner of turning on based on the time sequence. It can be understood that the time sequence shown in FIG. 2D is merely one of the embodiments; in another time sequence, the control signal Vc1 is enabled when the control signal Vc2 turns on the falling edge of the pulse, and the control signal Vc3 is enabled when the control signal Vc1 turns on the falling edge of the pulse.

It is to be noted that three constant on times Ton as shown in FIG. 2D may be same or different.

It can be understood that with incompletely same constant on times Ton, a plurality of switching amplifiers connected in parallel can handle the variability and complexity of the envelope signal. Further, the constant on time or the constant off time may be dynamically adjusted. In this case, each constant on time or constant off time may be calculated according to the first envelope signal or in combination with specific situations of the signal output by the first feeding-back unit, the first electrical signal and the signal of the supply voltage end, or in combination with the approach of how to determine the constant on time or the constant off time in the prior art. It can be understood that when the first driving unit has only one switching amplifier, the constant on time or the constant off time may also be determined naturally by referring to the above calculation manner.

For this reason, in another embodiment, the constant on time or the constant off time of at least one switching amplifier may be different from that of other switching amplifiers.

As shown in FIG. 2E, in another embodiment, the i switching amplifiers are series-connected with corresponding inductors and then connected in parallel to constitute the first driving unit. At this time, S7 is led out from the common end of all inductors connected in parallel.

In another embodiment, when the value of the electrical signal in the branch to which any switching amplifier connected in parallel belongs is less than the threshold of the branch, the first controlling unit is further configured to force the power supply to continuously provide the electrical signal in the branch to which any switching amplifier belongs in the constant on time control mode or the constant off time control mode, so that the value of the electrical signal in the branch is greater than or equal to the threshold of the branch; or

when the values of the electrical signals in the branches to which all switching amplifiers connected in parallel belong are added as the value of the first electrical signal, if the value of the first electric signal is less than the first threshold, the first controlling unit is further configured to force the power supply to continuously provide the first electrical signal in the constant on time control mode or the constant off time control mode, so that the value of the first electrical signal is greater than or equal to the first threshold.

In this embodiment, by referring to the previous embodiment of the first threshold, it can be understood that when the first driving unit includes a plurality of parallel-connected switching amplifiers in this embodiment, the startup of the COT control mode may be ensured according to the threshold of a particular branch in corresponding branches or the corresponding first threshold after the values of electrical signals in all branches are added so as to maximize the stability.

The prior art and the present invention are compared below in combination with the drawings.

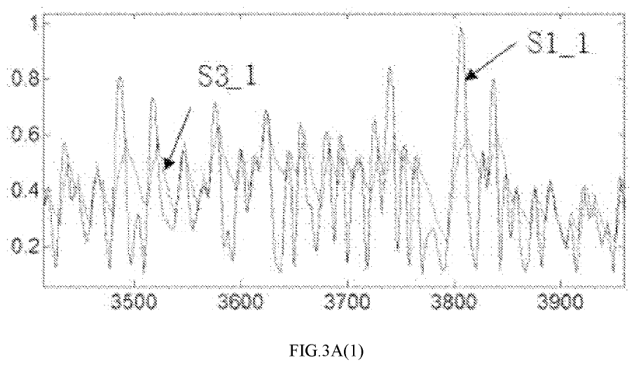

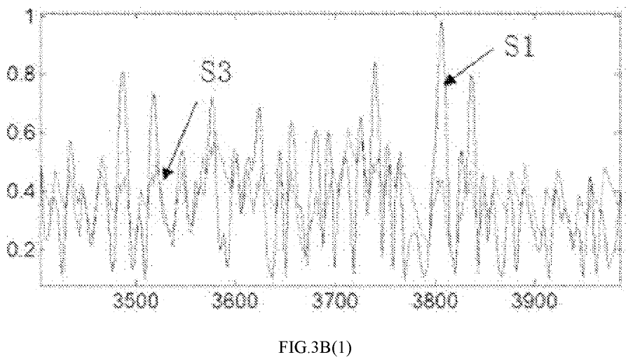

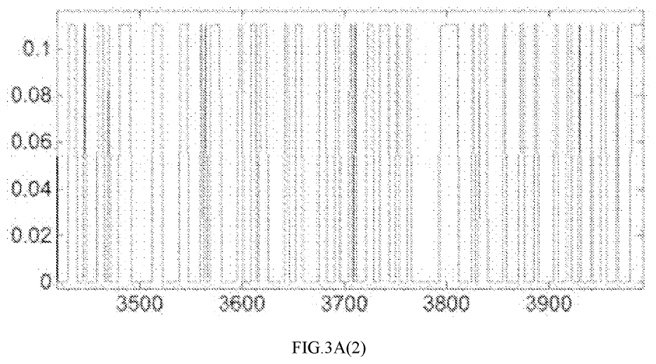

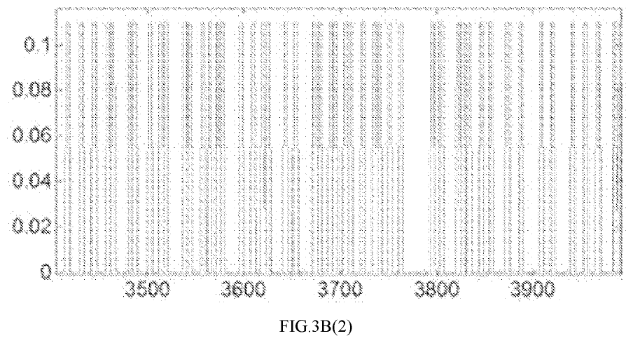

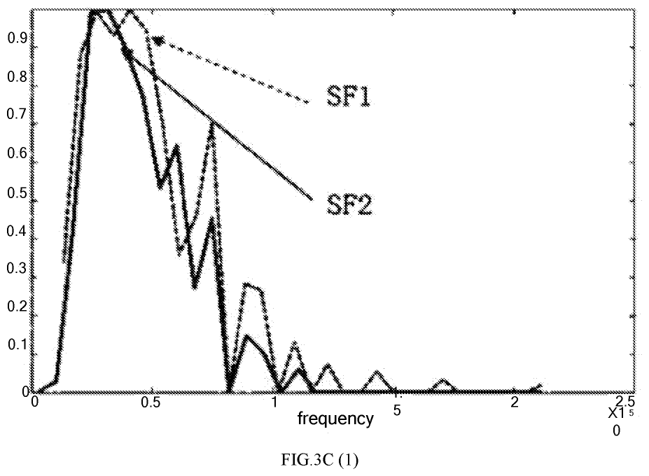

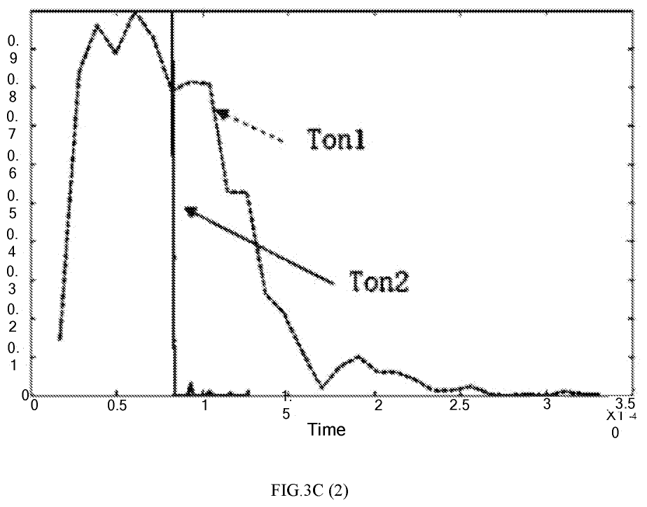

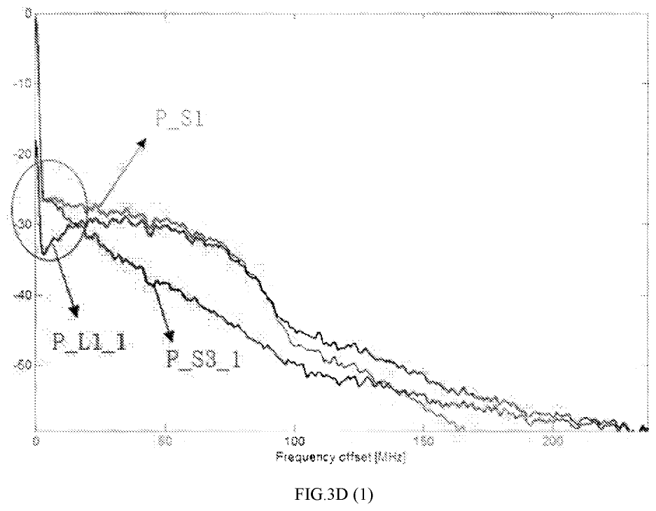

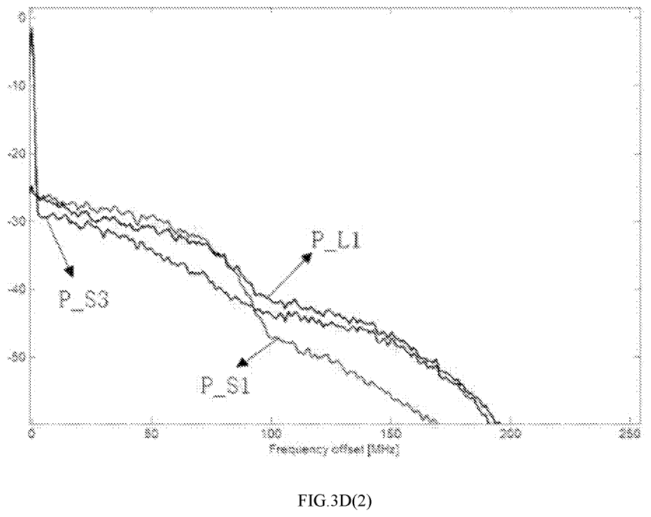

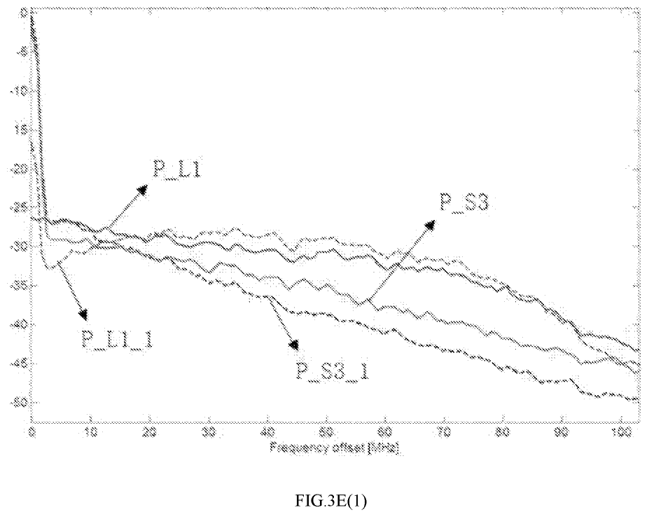

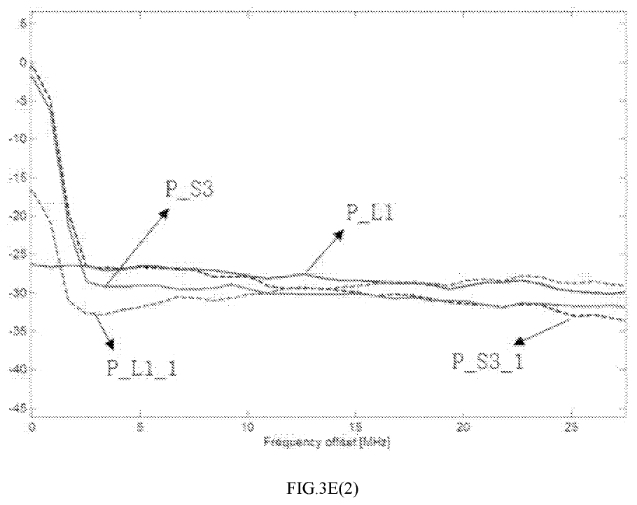

FIG. 3A (1) is a simulation diagram of a traditional hysteresis control power supply in a case of a first envelope signal being a signal of 100 MHz, and FIG. 3B (1) is a switching waveform of a driving unit corresponding to a switching power supply of the traditional hysteresis control power supply, where a signal S3_1 refers to a first electrical signal output by the driving unit, and a signal S1 refers to a first envelope signal.

FIG. 3A (2) is a simulation diagram of a power supply in a case of the same first envelope signal being the signal of 100 MHz according to an embodiment of the present invention, and FIG. 3B (2) is a switching waveform of a first driving unit corresponding to a switching power supply of the power supply, where a signal S3 refers to the first electrical signal according to the embodiment of the present invention, and the signal S1 refers to the same first envelope signal as adopted by the traditional hysteresis control power supply.

In FIG. 3A (1), FIG. 3B (1), FIG. 3A (2) and FIG. 3B (2), the ordinate refers to a normalized electric current signal size (unit: Ampere), and the abscissa refers to a signal sampling time (unit: 1 nsec/per sample). It can be known by comprehensively comparing the four diagrams that the first electrical signal S3 output by the first driving unit corresponding to the switching power supply in the power supply disclosed by the present invention is obviously closer to the first envelope signal S3, which indicates that the power supply disclosed by the present invention optimizes an optimal on-time point in the COT control mode.

In addition, FIG. 3C (1) illustrates a comparison of switching frequency distributions of the traditional hysteresis control power supply and the power supply according to the embodiments of the present invention described above, where the ordinate refers to a normalized statistical distribution amount (unit: number), the abscissa refers to an on/off switching frequency (unit: 100 MHz), SF1 refers to switching frequency distribution of the traditional hysteresis control power supply, and SF2 refers to switching frequency distribution of the power supply according to the embodiment of the present invention. It can be known from the comparison of diagrams that the power supply of the present invention can significantly reduce an average switching frequency; the average switching frequency is reduced from 50 MHz to 35 MHz through simulation calculation in this embodiment.

FIG. 3C (2) illustrates a comparison of switch-on time distributions of the traditional hysteresis control power supply and the power supply according to the embodiments of the present invention described above, where the ordinate refers to a normalized on-time statistical distribution amount (unit: number), the abscissa refers to the on time (unit: 10 nsec), Ton1 refers to switch-on time distribution of the traditional hysteresis control power supply, and Ton2 refers to switch-on time distribution of the power supply according to the embodiments of the present invention. It can be known from the comparison of diagrams that the switch-on time distribution of the power supply according to the present invention is far lower than that of the traditional hysteresis control power supply, the switch-on time of the power supply according to the present invention may be basically fixed, resulting in a very strong anti-interference capability, and increasing a control accuracy of the optimal on-time point of the COT control mode. The switch-on time is about 8-9 ns based on simulation calculation in this embodiment.

Further, FIG. 3D (1) illustrates a power simulation of each unit of the above traditional hysteresis control power supply in a working process, and FIG. 3D (2) illustrates a power simulation of each unit of the above power supply in a working process according to the embodiments of the present invention, where the ordinate refers to a normalized power frequency spectrum (unit: dBm/Hz), the abscissa refers to a bandwidth (unit: MHz), P_S1 refers to power of the first envelope signal, P_L1_1 refers to power of the linear amplification unit in the traditional hysteresis control power supply, P_S3_1 refers to power of the switching power supply in the traditional hysteresis control power supply, P_L1 refers to power of the linear amplification unit in the power supply of the embodiments, and P_S3 refers to power of the switching power supply in the power supply of the embodiments. By comparing FIG. 3D (1) with FIG. 3D (2), especially by comparing a circled portion in FIG. 3D (1) with a low frequency band region corresponding to a corresponding portion in FIG. 3D (2), it can be known that a power output proportion of the linear amplification unit is relatively high in the traditional hysteresis control power supply; however, a power proportion of the switching power supply is increased in the power supply of the embodiments, especially the power supply of the embodiments has significant advantages in the low frequency band power output over the traditional hysteresis control power supply, and most energy (which may be considered as 99% energy) of an envelope of the radio-frequency signal is concentrated below 20 MHz. Therefore, the power supply of the embodiments effectively suppresses the power output of the linear amplifier and improves the efficiency of the entire power supply system. Since the efficiency of the switching power supply is higher than the efficiency of the linear amplification unit, the efficiency of the power supply according to the embodiments of the present invention is significantly improved compared with the prior art.

Further, based on FIG. 3D (1) and FIG. 3D (2), in terms of the low frequency band, FIG. 3E (1) illustrates a comparison situation of change curves of output powers, along with a frequency, of the traditional hysteresis control power supply and the power supply according to the embodiments of the present invention within a low frequency range of 0 MHz to 100 MHz, and FIG. 3E (2) illustrates a comparison situation of change curves of the output powers, along with the frequency, of the traditional hysteresis control power supply and the power supply according to the embodiments of the present invention within a lower frequency range of 0 MHz to 25 MHz.

It can be known from the diagrams that the power curve P_L1_1 of the linear amplification unit in the traditional hysteresis control power supply is convex downward at about 2.5 MHz of the low frequency band, which indicates that the linear amplification unit thereof outputs higher power and will also bring larger loss; however, in the present invention, the output power of the linear amplification unit is obviously lower than the output power of the linear amplification unit of the hysteresis control power supply in the prior art in a case of the same frequency within the frequency range of less than 20 MHz, and most energy (which may be considered as 99% energy) of the envelope of the radio-frequency signal is concentrated below 20 MHz. Therefore, it fully indicates that the embodiment of the present invention has excellent performance in the low frequency range significantly, improving the efficiency of the entire power supply.

In addition, in some embodiments, the controlling unit may be provided on a chip or processor (e.g., silicon) of a digital transmitter. Furthermore, the driving unit may also be provided on the chip or processor of the digital transmitter. Similarly, the remaining units may also be provided on the relevant chip or processor. The above power supply may also be provided on the chip or processor of the digital transmitter naturally.

The embodiments of the present invention may be implemented by hardware or software according to specific implementation requirements. The implementation may be executed by using a digital storage medium (such as a floppy disk, a Digital Video Disk (DVD), Blu-ray, a compact disk (CD), a Read-Only Memory (ROM), a Programmable Read-Only Memory (PROM), an Erasable Programmable Read-Only Memory (EPROM), an Electrically Erasable Programmable Read-Only Memory (EEPROM) or a flash memory) storing electronically-readable control signals. Therefore, the digital storage medium may be computer readable.

In some embodiments, some or all functions of the method described herein may be executed by using a programmable logic device (e.g., a field programmable gate array). In some embodiments, the field programmable gate array may cooperate with a microprocessor to implement the power supply described herein.

The above embodiments are merely illustrative of principles of the present invention. It is to be understood that modifications and variations of arrangements and details described herein are apparent to those skilled in the art. Therefore, intentions are limited only by the scope of the following patent claims rather than specific details presented through the descriptions and explanations of the embodiments herein.

1. A feedback-based power supply for a radio-frequency power amplifier, comprising a linear amplification unit, a first controlling unit, a first driving unit, a first feeding-back unit and a superimposing unit, wherein the linear amplification unit is configured to linearly amplify a first envelope signal and output the linearly-amplified envelope signal; the first controlling unit comprises a first input end configured to receive the linearly-amplified envelope signal; the first controlling unit further comprises a second input end configured to obtain a feedback signal of a change rate of an electrical signal of a supply voltage end of the radio-frequency power amplifier through the first feeding-back unit; the first controlling unit further comprises an output end, wherein the first controlling unit outputs a first control signal based on inputs of the first input end and the second input end to enable the power supply to work in any one of the following modes: a constant on time control mode having a constant on time and a constant off time control mode having a constant off time; the first driving unit is configured to connect the output end of the first controlling unit and provide a first electrical signal based on the first control signal; and the superimposing unit is configured to superimpose the linearly-amplified envelope signal and the first electrical signal so as to supply power to the supply voltage end of the radio-frequency power amplifier.

2. The feedback-based power supply according to claim 1, wherein the first envelope signal preferably is an envelope signal input into the radio-frequency power amplifier.

3. The feedback-based power supply according to claim 1, wherein the change rate of the electrical signal of the supply voltage end comprises any one or combination of: a change rate of a voltage, a change rate of an electric current and a change rate of an envelope amplitude.

4. The feedback-based power supply according to claim 1, wherein the first driving unit comprises a first switching amplifier or comprises an upper power transistor and a lower power transistor.

5. The feedback-based power supply according to claim 1, further comprising a first mode selecting unit configured to perform selection between the constant on time control mode and the constant off time control mode.

6. The feedback-based power supply according to claim 1, wherein the first controlling unit comprises a timing unit configured to determine the constant on time or the constant off time.

7. The feedback-based power supply according to claim 1, wherein when a value of the first electrical signal is less than a first threshold, the first controlling unit is further configured to force the power supply to continuously provide the first electrical signal in the constant on time control mode or the constant off time control mode so that the value of the first electrical signal is greater than or equal to the first threshold.

8. The feedback-based power supply according to claim 1, wherein the first driving unit comprises at least a first switching amplifier and a second switching amplifier connected in parallel, and the first controlling unit is further configured to enable the first switching amplifier and the second switching amplifier to work in the constant on time control mode or the constant off time control mode according to a time sequence.

9. The feedback-based power supply according to claim 8, wherein the constant on time or the constant off time of at least one switching amplifier is different from that of other switching amplifiers.

10. The feedback-based power supply according to claim 8, wherein when the value of the electrical signal in a branch to which any switching amplifier connected in parallel belongs is less than a threshold of the branch, the first controlling unit is further configured to force the power supply to continuously provide the electrical signal in the branch to which any switching amplifier belongs in the constant on time control mode or the constant off time control mode so that the value of the electrical signal in the branch is greater than or equal to the threshold of the branch; or when the values of the electrical signals in the branches to which all switching amplifiers connected in parallel belong are added as the value of the first electrical signal and the value of the first electric signal is less than the first threshold, the first controlling unit is further configured to force the power supply to continuously provide the first electrical signal in the constant on time control mode or the constant off time control mode so that the value of the first electrical signal is greater than or equal to the first threshold.
